(19) United States
(12) Patent Application Publication
(10) Pub. No.: US 2014/0003020 A1
(43) Pub. Date: Jan. 2, 2014

(54) CIRCUIT BOARD MOUNTING APPARATUS

(71) Applicants: CHIEN-CHUNG HUANG, New Taipei (TW); ZHENG-HENG SUN, New Taipei (TW)

(72) Inventors: CHIEN-CHUNG HUANG, New Taipei (TW); ZHENG-HENG SUN, New Taipei (TW)

(21) Appl. No.: 13/678,564

(22) Filed: Nov. 16, 2012

(30) Foreign Application Priority Data
Jun. 29, 2012 (CN) 2012102211385

(51) Int. Cl. H05K 5/02

(52) U.S. Cl. CPC H05K 5/0204
USPC 361/807

(57) ABSTRACT

A circuit board mounting apparatus includes a circuit board, a chassis, a first mounting member, a second mounting member, and a fastener. The chassis includes a side plate defining a through hole, a first hole, and a second hole communicating with the first hole. The first and second mounting members are detachably mounted to a front side of the circuit board. A neck protrudes from a front end of the first mounting member, and a head is formed on a front end of the neck. The neck extends through the first hole and engages in the second hole. The head abuts the front side of the side plate. A fixing hole is defined in a front end of the second mounting member. The fastener extends through the through hole and engages in the fixing hole, to perpendicularly fix the circuit board to the side plate.

### BACKGROUND

1. Technical Field

The present disclosure relates to a circuit board mounting apparatus.

2. Description of Related Art

In electronic devices, circuit boards may be mounted inside the devices with a number of screws extended through the circuit board and engaged in a number of posts on a bottom wall of the chassis of the devices. However, fastening screws manually in the chassis can be difficult and inconvenient because of limited space for maneuvering.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a circuit board mounting apparatus, wherein the circuit board mounting apparatus includes a first mounting member and a second mounting member.

FIG. 2 is similar to FIG. 1, but viewed from another perspective.

FIG. 3 is an enlarged view of the first mounting member of FIG. 1.

FIG. 4 is an enlarged view of the second mounting member of FIG. 1.

FIG. 5 is an assembled, isometric view of FIG. 2.

FIG. 6 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”.

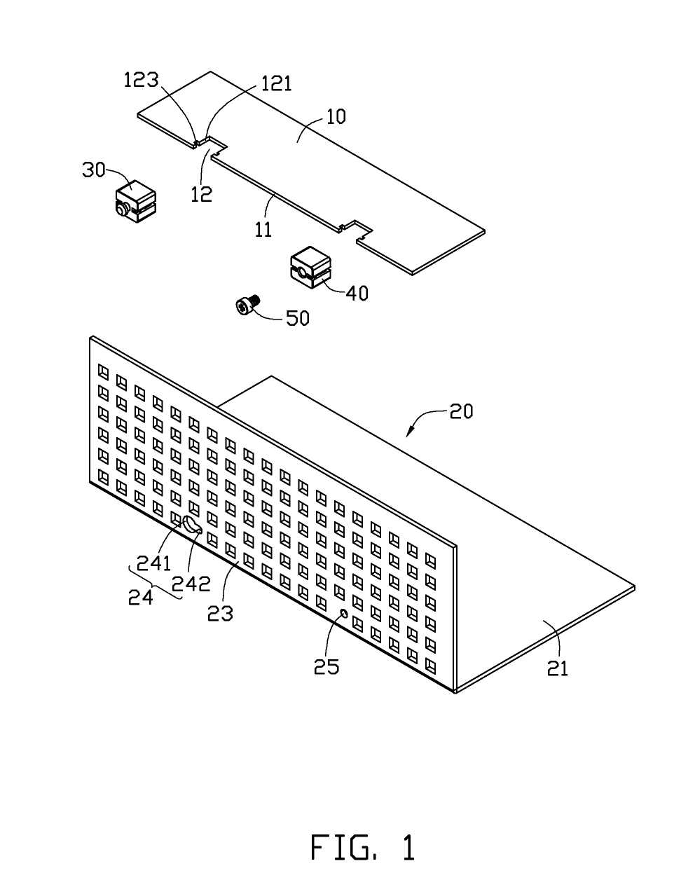

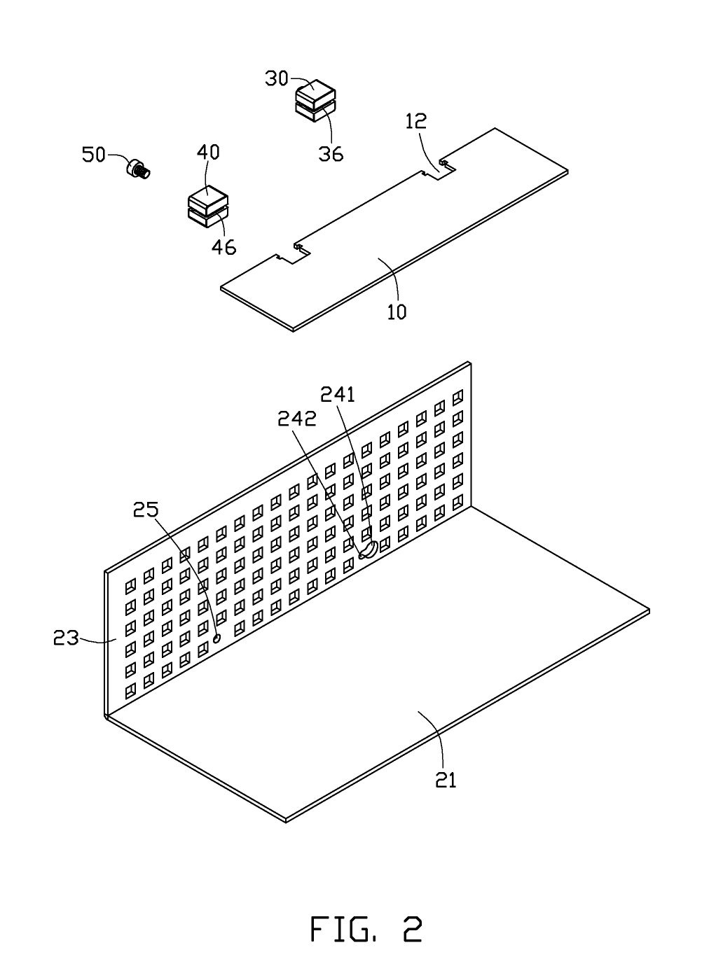

FIGS. 1 and 2 show a circuit board mounting apparatus of the embodiment. The circuit board mounting apparatus includes a circuit board 10, a chassis 20, a first mounting member 30, a second mounting member 40, and a fastener. In the embodiment, the fastener is a screw 50.

Two slots 12 are defined in a front side 11 of the circuit board 10. The circuit board 10 forms two sidewalls 121 bounding opposite sides of each slot 12. A notch 123 is defined in each sidewall 121 adjacent to a front end of the sidewall 121.

The chassis 20 includes a bottom plate 21 and a side plate 23 extending up from the front side of the bottom plate 21. A slide hole 24 and a through hole 25 are defined in the side plate 23, adjacent to the bottom plate 21. The slide hole 24 includes a first hole 241 away from the through hole 25, and a second hole 242 adjacent to the through hole 25 and communicating with the first hole 241. A diameter of the first hole 241 is greater than a diameter of the second hole 242.

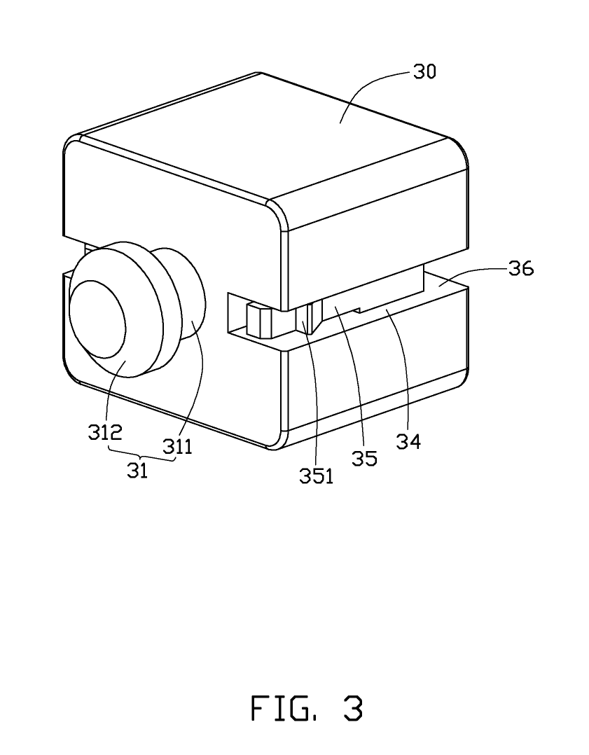

FIG. 3 shows a latching portion 31 protruding from the front end of the first mounting member 30. The latching portion 31 includes a columnar neck 311 connected to the first mounting member 30, and a head 312 formed on the front end of the neck 311. A diameter of the head 312 is greater than a diameter of the neck 311. Two first recesses 34 are respectively defined in opposite sides of the first mounting member 30, extending horizontally through the front end and the rear end of the first mounting member 30. A second recess 36 is defined in the rear end of the first mounting member 30, with opposite ends of the second recess 36 communicating with the corresponding first recesses 34. A resilient arm 35 slantingly extends forward and outward from a sidewall of each first recess 34. A hook 351 protrudes from an outer side of each resilient arm 35 adjacent to the front end of the resilient arm 35.

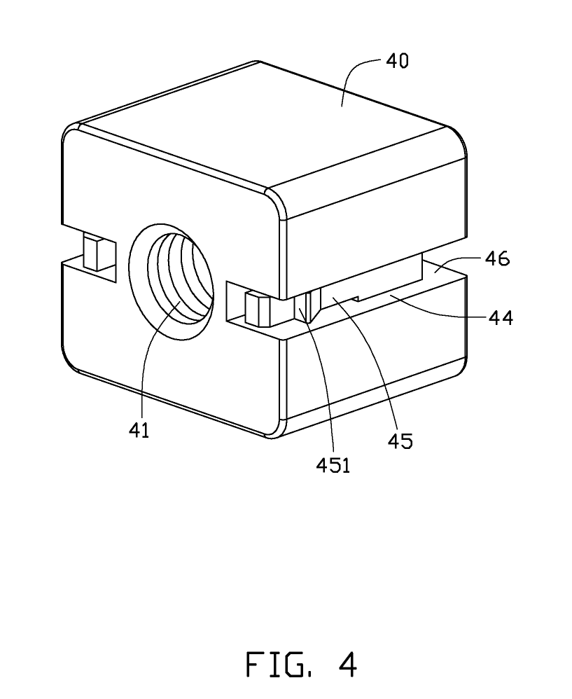

FIG. 4 shows that a horizontally extending fixing hole 41 is defined in the front end of the second mounting member 40. Two first recesses 44 are respectively defined in opposite sides of the second mounting member 40, extending horizontally through the front end and the rear end of the second mounting member 40. A second recess 46 is defined in the rear end of the second mounting member 40, with opposite ends of the second recess 46 communicating with the corresponding first recesses 44. A resilient arm 45 slantingly extends forward and outward from a sidewall of each first recess 44. A hook 351 protrudes from an outer side of each resilient arm 45 adjacent to the front end of the resilient arm 45.

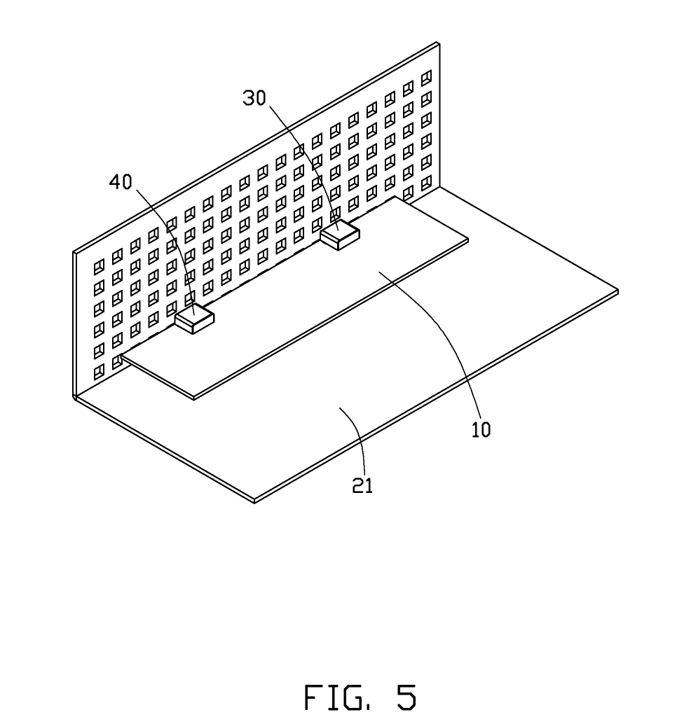

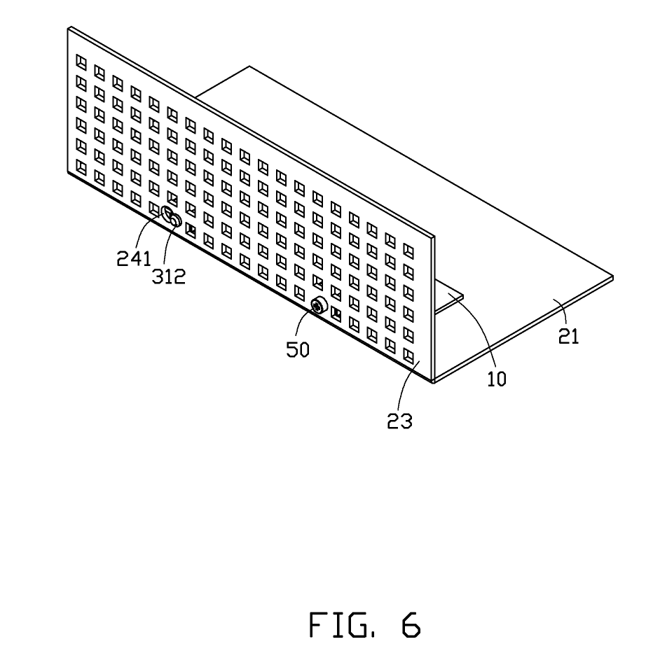

FIGS. 5 and 6 show that in assembly, the first and second mounting members 30 and 40 are placed in front of the front side 11 of the circuit board 10, with the first and second mounting members 30 and 40 respectively aligning with the slots 12. The first and second mounting members 30 and 40 are moved backward, to allow the sidewalls 121 bounding the slots 12 to engage in the first recesses 34 and 44 of the first and second mounting members 30 and 40. The hooks 351 and 451 abut the corresponding sidewalls 121, to deform the corresponding resilient arms 35 and 45 inwardly. The first and second mounting members 30 and 40 are further moved backward, until portions of the circuit board 10 bounding the rear ends of the slots 12 engage in the second recesses 36 and 46. The resilient arms 35 and 45 are restored, to engage the hooks 351 and 451 in the corresponding notches 123. Thereby, the first and second mounting members 30 and 40 are fixed to the front side 11 of the circuit board 10. The latching portion 31 and the fixing hole 41 are parallel to the circuit board 10.

The circuit board 10 is placed in the chassis 20, to allow the head 312 to extend through the first hole 241. The neck 311 is received in the first hole 241, and the front ends of the first and second mounting members 30 and 40 abut the rear side of the side plate 23. The circuit board 10 is slid horizontally along the side plate 23, to allow the neck 311 to engage in the second hole 242. The head 312 abuts the front side of the side plate 23. The fixing hole 41 aligns with the through hole 25. The screw 50 extends through the through hole 25 and engages in the fixing hole 41. Thereby, the circuit board 10 is perpendicularly mounted to the side plate 23.

There is only one screw 50 to be installed when mounting the circuit board 10, and the screw 50 is installed from outside of the chassis 20, which is convenient.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A circuit board mounting apparatus, comprising:
a circuit board;
a chassis comprising a side plate defining a through hole, a first hole, and a second hole communicating with the first hole, wherein a diameter of the first hole is greater than a diameter of the second hole;
a first mounting member detachably mounted to a front side of the circuit board, wherein a neck protrudes from a front end of the first mounting member, and a head is formed on a front end of the neck, the neck extends through the first hole and slides to engage in the second hole, the head abuts the a side of the side plate;
a second mounting member detachably mounted to the front side of the circuit board, wherein a fixing hole parallel to the circuit board is defined in a front end of the second mounting member; and
a fastener extending through the through hole of the side plate and engaging in the fixing hole of the second mounting member.

2. The circuit board mounting apparatus of claim 1, wherein a slot is defined in the front side of the circuit board, the circuit board forms two sidewalls bounding opposite sides of the slot, two first recesses are respectively defined in opposite sides of the first mounting member, the sidewalls bounding the slot are slidably engaged in the first recesses of the first mounting member, and the first mounting member forms at least one hook to lock to the circuit board.

3. The circuit board mounting apparatus of claim 2, wherein a notch is defined in each sidewall, a resilient arm slantingly extends forward and outward from each first recess, the number of the at least one hook is two, said two hooks respectively protrude from outer sides of the resilient arms of the first mounting member, to respectively engage in the notches of the corresponding sidewalls.

4. The circuit board mounting apparatus of claim 3, wherein the notches are respectively defined in the sidewalls adjacent to front ends of the sidewalls, and the hooks are respectively formed on the resilient arms adjacent to front ends of the resilient arms.

5. The circuit board mounting apparatus of claim 2, wherein a second recess is defined in a rear end of the first mounting member, with opposite ends of the second recess communicating with the first recesses of the first mounting member, portions of the circuit board bounding a rear end of the slot engages in the second recess.

6. The circuit board mounting apparatus of claim 1, wherein a slot is defined in the front end of the circuit board, the circuit board forms two sidewalls bounding opposite sides of the slot, two first recesses are respectively defined in opposite sides of the second mounting member, the sidewalls bounding the slot are slidably engaged in the first recesses of the second mounting member, and the second mounting member forms at least one hook to lock to the circuit board.

7. The circuit board mounting apparatus of claim 6, wherein a notch is defined in each sidewall, a resilient arm slantingly extends forward and outward from each first recess, the number of the at least one hook is two, said two hooks respectively protrude from outer sides of the resilient arms of the second mounting member, to respectively engage in the notches of the corresponding sidewalls.

8. The circuit board mounting apparatus of claim 7, wherein the notches are respectively defined in the sidewalls adjacent to front ends of the sidewalls, and the hooks are respectively formed on the resilient arms adjacent to front ends of the resilient arms.

9. The circuit board mounting apparatus of claim 6, wherein a second recess is defined in a rear end of the second mounting member, with opposite ends of the second recess communicating with the first recesses of the second mounting member, portions of the circuit board bounding a rear end of the slot engages in the second recess.

10. The circuit board mounting apparatus of claim 1, wherein the second hole is arranged between the first hole and the through hole.

11. The circuit board mounting apparatus of claim 1, wherein a diameter of the head is greater than a diameter of the neck.

12. The circuit board mounting apparatus of claim 1, wherein the front ends of the first and second mounting members abut a rear side of the side plate.
